(19) United States
(12) Patent Application Publication
(10) Pub. No.: US 2025/0244410 A1
(43) Pub. Date: Jul. 31, 2025

(54) ELECTRONIC DEVICE, SYSTEM AND INDUCTIVE SWITCHING TEST METHOD

(71) Applicant: Texas Instruments Incorporated, Dallas, TX (US)

(72) Inventors: Xiangdong Xuan, Lewisville, TX (US); Indumini Ranmuthu, Plano, TX (US); Divya Hansraj, Center Valley, PA (US); Mustapha El-Markhi, Richardson, TX (US)

(21) Appl. No.: 18/429,091

(22) Filed: Jan. 31, 2024

(51) Int. Cl. G01R 31/72; H03K 17/06; H03K 17/687

(52) U.S. Cl. CPC G01R 31/72; H03K 17/063; H03K 17/687

(57) ABSTRACT

An electronic device includes a transistor having first and second transistor terminals and a control terminal, a control circuit connected to the control terminal, a first device terminal connected to the first transistor terminal, a second device terminal connected to the second transistor terminal, and a clamp circuit connected between the first transistor terminal and the control terminal. A test method includes connecting a capacitor to the first device terminal, connecting an output circuit to the second device terminal, precharging the capacitor, disconnecting a precharge circuit from the capacitor, precharging an inductor, connecting the inductor to the first device terminal while the precharge circuit is disconnected, and testing the transistor while a test current is flowing.

### BACKGROUND

Inductive switching allows testing of transistors in electronic devices for electrical performance and reliability evaluation in development and production applications. Dedicated bench equipment can be used for unclamped inductive switching (UIS) or clamped inductive switching (CIS) transistor testing, but this type of tester requires manual operations and is unsuitable for automation to test large sample sizes in electronic device manufacturing. High-volume automated test equipment (ATE) can be used for testing dedicated transistor devices, but high-volume CIS testing is difficult where the device design does not provide external access to the transistor terminals. Integrated power modules and other electronic devices can include internal drivers and switching control circuitry to operate field effect transistor (FET) gate terminals or other transistor control terminals, and the control terminal may not be connected to a device lead for access during testing.

### SUMMARY

In one aspect, an electronic device includes a transistor having first and second transistor terminals and a control terminal, as well as a control circuit connected to the control terminal, a first device terminal connected to the first transistor terminal, a second device terminal connected to the second transistor terminal, and a clamp circuit connected between the first transistor terminal and the control terminal.

In another aspect, a test system includes a controller, a test inductor having a first inductor terminal, and a second inductor terminal coupled to a supply, a switching circuit coupled to the test inductor and having an output adapted to be connected to a first device terminal of an electronic device under test (DUT), an output circuit adapted to be connected to a second device terminal of the DUT, a measurement circuit configured to measure a voltage between the first and second device terminals, a test capacitor adapted to be connected to the first device terminal, and a precharge circuit configured to selectively provide a precharge current to the first device terminal. The controller is configured to operate the precharge circuit in a first precharge mode to provide the precharge current to the first device terminal to precharge the test capacitor when the test capacitor is connected to the first device terminal, and then operate the precharge circuit in a second precharge mode to stop the precharge current to the first device terminal. The controller is also configured to selectively operate the switching circuit in a first switching circuit mode to connect the first inductor terminal to a precharge load to develop a test current in the test inductor, and in a second switching circuit mode to connect the first inductor terminal to the output of the switching circuit to cause the test current to flow into the first device terminal while the precharge circuit is in the second precharge mode. The controller is also configured to operate the measurement circuit to measure the voltage between the first and second device terminals while the switching circuit is in the second switching circuit mode and the precharge circuit is in the second precharge mode.

In another aspect, a method includes connecting a first capacitor terminal of a test capacitor to a first device terminal of an electronic DUT, connecting an output circuit to a second device terminal of the DUT, connecting a second capacitor terminal of the test capacitor to a third device terminal of the DUT, precharging the test capacitor using a precharge circuit, disconnecting the precharge circuit from the test capacitor, precharging a test inductor to develop a test current in the test inductor, as well as connecting the test inductor to cause the test current to flow from the test inductor into the first device terminal while the precharge circuit is disconnected from the test capacitor, and testing the transistor of the DUT while the test current is flowing into the first device terminal.

### BRIEF DESCRIPTION OF THE DRAWINGS

FIG. 1 is a schematic diagram of a test system with automatic test equipment configured to perform clamped inductive switching testing of first and second transistors in an installed electronic DUT.

FIG. 2 is a flow diagram of a test method for testing an electronic DUT.

FIG. 2A is a flow diagram of a characterization method.

FIG. 3 is a graph of drain-source voltage during CIS testing of a first high side transistor of the electronic DUT.

FIG. 4 is a graph of drain-source voltage during CIS testing of a second low side transistor of the electronic DUT.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately,” or “substantially” preceding a value means +/−10 percent of the stated value.

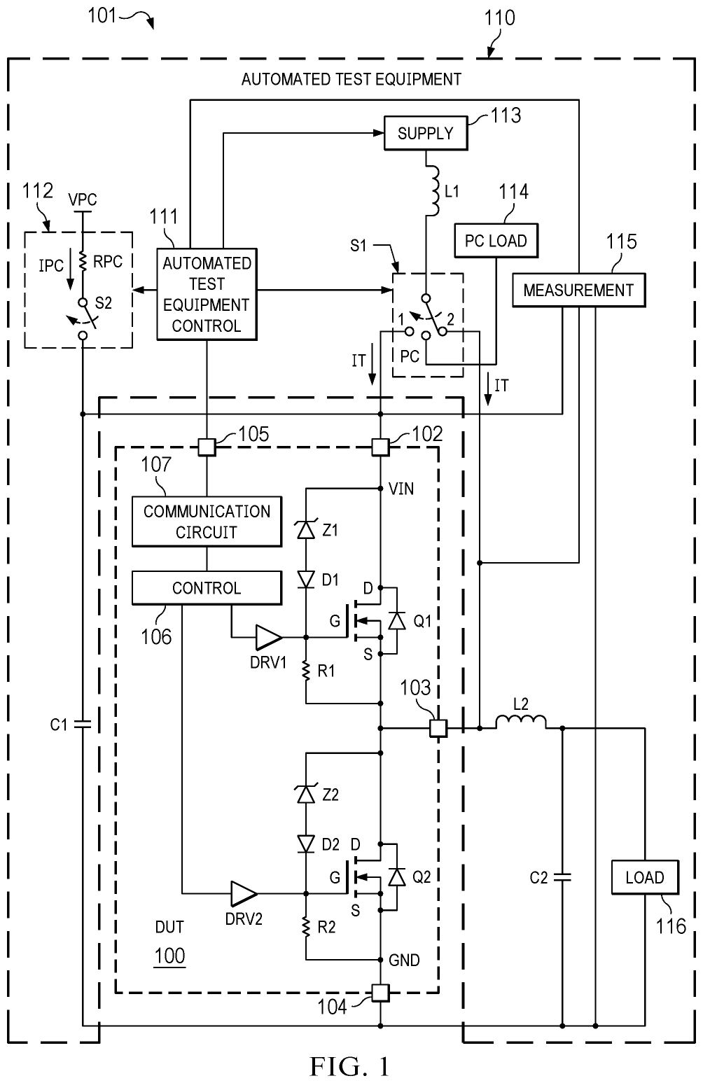

FIG. 1 schematically illustrates an electronic device 100, also referred to as an electronic DUT or Dut, in a test system 101 with automatic test equipment (ATE) 110 configured to perform clamped inductive switching (CIS) testing of one or more transistors in an installed electronic DUT 100. The electronic device 100, the described ATE 110, and the testing methods described hereinafter facilitate high-volume automated production testing of manufactured electronic devices including CIS testing of one or more transistors integrated into the tested electronic devices 100. In the illustrated example, the electronic device 100 includes active clamp circuitry to protect the internal transistor(s) from overvoltage conditions during production testing as well as in and use operation, as well as to mitigate FET avalanche operation during CIS testing in development and production. In other implementations, different types and forms of transistors can be provided with clamp circuitry in the electronic device, including without limitation bipolar transistors, IGBTs, etc.

The electronic device 100 in the illustrated example is an integrated power module device that includes a first FET transistor Q1 and a second FET transistor Q2 interconnected in a half bridge circuit as respective high and low side transistors. The transistors Q1 and Q2 each have first and second transistor terminals and a control terminal, where the first transistor terminal in this example is a drain D, the second transistor terminal is a source S, and the control terminal is a gate G. In other implementations, the transistor terminals and control terminal can be of a different form, such as emitter and collector transistor terminals and a base control terminal for bipolar transistors (not shown). The illustrated device 100 facilitates use in constructing power converters such as DC-DC converters for use in a host circuit board or system. Other electronic device implementations can have more or fewer than two internal transistors.

The drain D of the first transistor Q1 in this example is referred to as a first transistor terminal, the source S of the first transistor Q1 is referred to as a second transistor terminal, and the gate G of the first transistor Q1 is referred to as a first control terminal. The electronic device 100 has device terminals or leads, including a first device terminal 102 connected to the first transistor terminal D of the first transistor Q1, and a second device terminal 103 connected to the second transistor terminal S of the first transistor Q1. In the illustrated electronic device 100, the drain of the first transistor Q1 operates as an input voltage node labeled “VIN” with external conductivity via the first device terminal 102. In addition, the source of the first transistor Q1 is connected to the drain of the second transistor Q2 to form a switching node with external access for conductivity to an output circuit by the second device terminal 103. The electronic device 100 also has a third device terminal 104 connected to the source S of the second transistor Q2, which operates as a reference or ground connection labeled “GND” for operation of the electronic device 100 in a DC-DC converter circuit or system. The illustrated example also includes a fourth device terminal 105 as shown in FIG. 1 and may include further device terminals (not shown).

In operation of the test system 101, the electronic device 100 is installed as a DUT in a socket or other suitable interconnection structure that provides electrical connection to the device terminals 102-105 for CIS testing and other production testing of the DUT 100. However, the gate control terminal G of the first transistor Q1 is not directly connected to any device terminal. Instead, the electronic device 100 in this example has internal control and driver circuitry including a first driver circuit DRV1 and a control circuit 106 configured to operate the first control terminal or gate G of the first transistor Q1. In addition, the electronic device includes a second driver circuit DRV2 configured to operate the second control terminal or gate G of the second transistor Q1.

The illustrated example also includes a communication circuit 107 connected to the control circuit 106 and having external communications connections via the fourth device terminal 105. The communications circuit 107 in this example provides external control of the transistors Q1 and Q2 by connection of the control circuit 106 to the gate control terminals of the transistors Q1 and Q2 via the respective associated driver circuits DRV1 and DRV2. The electronic device 100 may include further logic and/or control circuitry, for example, pulse width modulation switching control logic, and may include programmed and/or programmable elements (not shown) to facilitate operation as a power module to implement one or more power conversion functions when installed in a host system (not shown).

The electronic device 100 includes integrated clamp circuits that provide self-protection against voltage stress and facilitates clamped inductive switching (CIS) testing of the transistors Q1 and Q2 even though the gate control terminals G are not directly connected to any device terminal. A first clamp circuit D1, Z1 is connected between the first transistor terminal D and the control terminal G to protect the first transistor Q1 and a second clamp circuit D2, Z2 is connected between the second transistor terminal D and the second control terminal G to protect the second transistor Q2. The clamp circuits augment the device 100 with a distributed clamp to protect the respective transistors Q1 and Q2 from damage under overvoltage conditions in operation or in production and during CIS testing in the ATE 110. In operation during field use or in the ATE 110, the clamp turns on if a respective drain voltage rises high enough in order to clamp the device voltage and prevent the stress across the FET. In CIS testing, the ATE provides a large test current IT to the tested FET transistor Q1 or Q2. The internal clamp enables CIS testing by clamping the voltage across the FET to prevent FET breakdown under this test condition, and the illustrated example helps ensure that the high and low side transistors Q1 and Q2 do not go into avalanche mode.

In the illustrated example, the first clamp circuit includes a p-n junction diode D1 and a Zener diode Z1 connected in series with one another between the first transistor terminal D and the control terminal G of the first transistor Q1. The p-n junction diode D1 includes a first anode and a first cathode, with the first cathode directly connected to the control terminal G of the first transistor Q1. The first Zener diode Z1 includes a second anode and a second cathode, with the second anode directly connected to the first anode, and the second cathode directly connected to the first transistor terminal D of Q1. The second clamp circuit includes a second p-n junction diode D2 and a second Zener diode Z2 connected in series with one another between the second transistor terminal D and the control terminal G of the second transistor Q2. The second p-n junction diode D2 includes a first anode and a first cathode, with the first cathode directly connected to the control terminal G of the second transistor Q2. The second Zener diode Z2 includes a second anode and a second cathode, with the second anode directly connected to the first anode, and the second cathode directly connected to the second transistor terminal D of Q2.

The electronic device 100 in this example also includes a first resistor R1 connected between the control terminal G and the second transistor terminal S of the first transistor Q1, as well as a second resistor R2 connected between the second control terminal G and the second transistor terminal S of the second transistor Q2. In response to current flow of the test current IT into the clamp circuit, the first resistor R1 increases the gate-source voltage of the tested transistor Q1 to help ensure the transistor Q1 does not enter avalanche mode, and the second resistor R2 provides a similar function with respect to CIS testing of the second transistor Q2. The operation of the Zener diodes Z1 and Z2 controls the maximum clamp voltage of the respective transistor Q1 or Q2, for example, to limit the drain-source voltage across the tested transistor to avoid or mitigate voltage breakdown during CIS testing.

The ATE 110 includes a controller 111, a precharge circuit 112, a test capacitor C1, a supply 113, a test inductor L1 a switching circuit S1, a precharge load 114, a measurement circuit 115, and an output circuit with an output inductor L2, a load capacitor C2, and a resistive load 116. The ATE controller 111 in one example includes a programmed or programmable processor and an electronic memory for storing data and program instructions which, when executed by the processor, implement automated CIS testing and other automated test functions suitable for testing one or more electrical parameters or operating characteristics of a tested DUT 100. The controller 111 is configured by suitable program instructions to operate the test inductor L1, the supply 113, and the switching circuit S1 to selectively connect the test inductor L1 between the supply 113 and the precharge load 114 to precharge the test inductor L1 to develop a test current IT flow in the test inductor L1, and then to selectively connect the test inductor L1 between the supply 113 and one of the first and second device terminals 102 or 103 to deliver the test current IT to the tested electronic DUT 100. The controller 111 also causes the measurement circuit 115 to measure one or more operating parameters of the tested DUT 100 while the test current IT is delivered to the DUT 100 and determines a pass or fail result for the CIS test of the transistors Q1 and Q2 based on the measurements. In the illustrated example, the controller 111 also operates the precharge circuit 112 to selectively close a switch S2 to cause a precharge current IPC to flow through a current limiting precharge resistor RPC from a precharge voltage supply VPC to precharge the test capacitor C1 to a suitable voltage level, and then to open the switch S2 prior to causing the switching circuit S1 to deliver the test current IT to the DUT 100.

The test inductor L1 has a first inductor terminal connected to the switching circuit S1, and a second inductor terminal coupled to a supply 113. The switching circuit S1 is coupled to the test inductor L1 and has an output labeled “1” in FIG. 1 that is adapted to be connected to the first device terminal 102 of the DUT 100, for example, by connection to a socket (not shown) that provides electrical interconnections to an installed DUT 100. The socket in one example also provides electrical connection interfaces to connect the output circuit L2, C2, 116 to the second device terminal 103 of the DUT 100 to form a switching node of a DC-DC converter of the test system 101. The measurement circuit 115 in this example is configured by socket connections to the device terminals 102, 103, and 104 to measure a voltage between the first and second device terminals 102 and 103 (e.g., a drain-source voltage of the first transistor Q1) as well as to measure a voltage between the second and third device terminals 103 and 104 (e.g., a drain-source voltage of the second device transistor Q2).

The test capacitor C1 is adapted to be connected between the first device terminal 102 and the ground connection at the third device terminal 104, and the precharge circuit 112 is configured to selectively provide the precharge current IPC to the first device terminal 102 four precharge in the test capacitor C1. The precharge to test capacitor C1 operates during CIS testing to mitigate or avoid diversion of the test current IT to charge input voltage node capacitance of the tested DUT 100 when the switching circuit S1 connects the test inductor L1 to either the first device terminal 102 or the second device terminal 103.

The controller 111 is configured to operate the precharge circuit 112 in a first precharge mode to close the switch S2 in order to provide the precharge current IPC to the first device terminal 102 to precharge the test capacitor C1 when the test capacitor C1 is connected to the first device terminal 102. The controller 111 is also configured to then operate the precharge circuit 112 in a second precharge mode to stop or otherwise discontinue flow of the precharge current IPC to the first device terminal 102, for example, by opening the switch S2 of the precharge circuit 112. In various implementations, the controller 111 is configured by suitable program instructions to precharge the test capacitor C1 and disconnect the precharge circuit 112 from the first device terminal 102 prior to connection of the precharge to test inductor L1 to the DUT 100, for example, by controlling the timing between the switching operations of the switch S2 and the switching circuit S1. In certain implementations, controller 111 can precharge the test capacitor C1 and the test inductor L1 can be pre-charged concurrently and/or the precharge in can partially overlapping time, for example, to facilitate speedy automated testing of the DUT 100, although not a requirement of all possible implementations.

For test inductor precharging, the controller 111 is also configured to selectively operate the switching circuit S1 in a first switching circuit mode (e.g., a “precharge” mode) to connect the first inductor terminal to the precharge load 114 (e.g., switch position labeled “PC” of the switching circuit S1 in FIG. 1) to develop the test current IT in the test inductor L1. The controller 111 then operates the switching circuit S2 in a second switching circuit mode (e.g., a “test” mode) to connect the first inductor terminal to the output 1 of the switching circuit S1 to cause the test current IT to flow into the first device terminal 102 while the precharge circuit 112 is in the second precharge mode. The controller 111 is further configured to operate the measurement circuit 115 to measure the voltage between the first and second device terminals 102 and 103 while the switching circuit S1 is in the second switching circuit mode (test mode) and the precharge circuit 112 is in the second precharge mode. This timing configuration ensures that the precharge voltage supply VPC and the current limiting precharge resistor RPC are disconnected from the DUT 100 when the test inductor L1 is connected to the first device terminal 102.

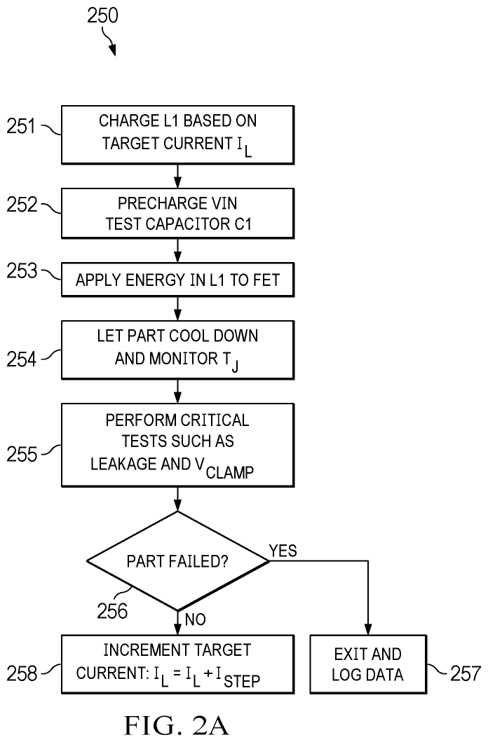

In operation, the controller 111 is configured to determine a pass or fail result for the first transistor Q1 based on the measured voltage between the first and second device terminals 102 and 103 (e.g., the drain-source voltage of Q1). In one example, the controller 111 is configured to determine a fail result for the first transistor Q1 if the measured voltage between the first and second device terminals 102 and 103 exceeds a threshold TH as illustrated and described further below in connection with FIG. 3.

In the illustrated implementation, the ATE 110 is configured to separately perform CIS testing of the second device transistor Q2, for example, after testing of the first transistor Q1 while the DUT 100 remains installed in the socket of the test system 101. In this example, the switching circuit S1 has a second output labeled “2” that is adapted to be connected to the second device terminal 103 (e.g., by suitable socket connections), and the measurement circuit 115 is configured to measure a second voltage between the second device terminal 103 and the third device terminal 104, which in this example corresponds to the drain-source voltage of the second transistor Q2. The controller 111 is configured to selectively operate the switching circuit S1 in a third switching circuit mode (e.g., another test mode, following a corresponding first switching circuit mode) to connect the first inductor terminal to the second output 2 of the switching circuit S1 to cause the test current IT to flow into the second device terminal 103 while the precharge circuit 112 is in the second precharge mode.

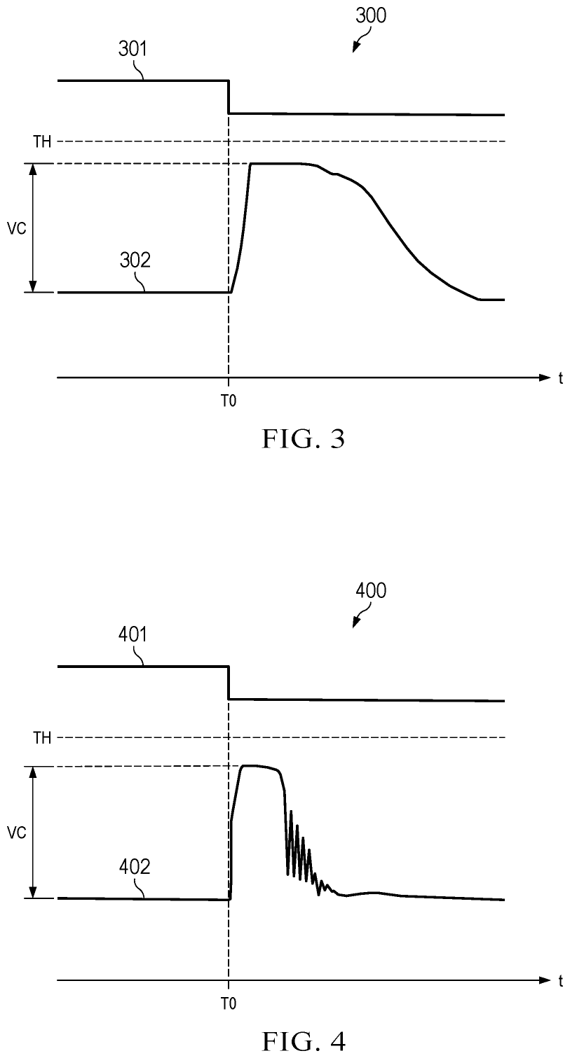

The controller 111 is configured to operate the measurement circuit 115 to measure the second voltage between the second device terminal 103 and the third device terminal 104 while the switching circuit S1 is in the third switching circuit mode and the precharge circuit 112 is in the second precharge mode. The controller 111 is configured to determine a pass or fail result for the second transistor Q2 based on the measured voltage between the second and third device terminals 103 and 104, for example, by determining a fail result if the measured voltage between the second and third device terminals 103 and 104 exceeds a threshold TH as illustrated and described further below in connection with FIG. 4.

The ATE can include further socket-type device connections to implement CIS testing of additional transistors of a given DUT design (not shown), for example, to perform CIS testing of any number of one or more transistors of a tested DUT, with suitable program instruction configuration of the controller 111 and any further required DUT interconnections for the switching circuit S1 and the measurement circuit 115. The pass or fail test criterion of the CIS testing can be implemented in one example by programming one or more thresholds (e.g., TH in FIGS. 3 and 4 below) into the memory of the controller 111 for comparison with measured values from the measurement circuit 115. The threshold or thresholds can be determined by empirical or programmatic characterization steps. In one example, one or more transistors of multiple DUTs 100 are tested, and the transistor or transistors are tested to incrementally increasing test current levels to determine the switched inductive current at which failure occurs. Failure current levels for multiple DUTs are evaluated to establish a somewhat lower test current for evaluating transistor CIS performance and reliability of production DUTs (e.g., a percentage of a maximum energy the device 100 can tolerate). The threshold or thresholds for production transistor CIS testing are determined and programmed into the controller 111 for automated testing of electronic devices during manufacturing.

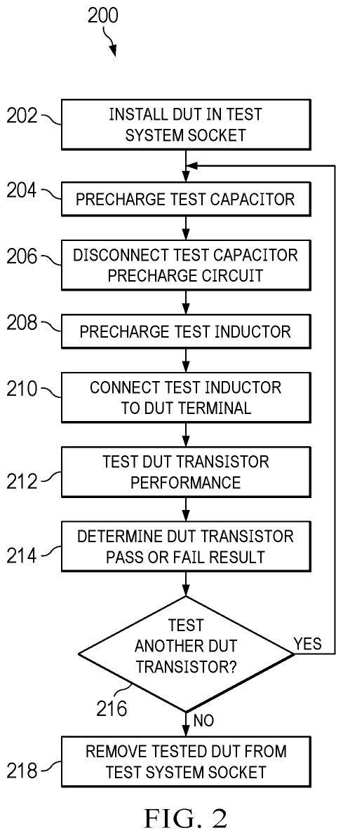

FIG. 2 shows an example test method 200 for testing an electronic DUT, such as the example DUT 100 undergoing automated CIS testing using the above-described system 101 of FIG. 1. The method 200 begins at 202 in FIG. 2 with electrical connection of suitable DUT device terminals (e.g., terminals 102-105 in FIG. 1) with the ATE 110. In one example, the electrical connection includes installing the DUT 100 and a test system socket of the system 101, including electrically connecting a first capacitor terminal of a test capacitor (e.g., C1) to the first device terminal 102 of the DUT 100, connecting the second capacitor terminal of the test capacitor to a reference terminal (e.g., the third device terminal 104), and connecting an output circuit (e.g., L2, C2, 116 in FIG. 1) to a second device terminal (e.g., the second device terminal 103) of the DUT 100.

The method 200 continues at 204 in FIG. 2 with pre-charging the test capacitor C1 using a precharge circuit (e.g., precharge circuit 112 in FIG. 1). At 206 and FIG. 2, the method includes disconnecting the precharge circuit 112 from the test capacitor C1. The method 200 continues at 208 with pre-charging a test inductor (e.g., L1) to develop a test current (e.g., IT) in the test inductor L1. The test inductor is connected to the DUT at 210 in FIG. 2 in order to cause the test current to flow from the test inductor L1 into the first device terminal 102 while the precharge circuit 112 is disconnected from the test capacitor C1. At 212, the transistor (e.g., Q1) of the DUT is tested while the test current IT is flowing into the first device terminal 102. In one example, the transistor testing at 212 includes measuring a voltage between first and second device terminals, for example, with the measurement circuit 115 measuring the voltage between the device terminals 102 and 103 in FIG. 1) while the test current IT is flowing into the first device terminal 102. At 214 in FIG. 2, the method 200 further includes determining a pass or fail result for the tested DUT transistor. In one example, the determination includes determining a transistor CIS test fail result if the measured voltage between the first and second device terminals 102 and 103 exceeds a threshold (e.g., TH in FIGS. 3 and/or 4).

The method 200 in one example includes selectively testing one or more other transistors of the installed DUT (e.g., Q2 in FIG. 1). At 216 in FIG. 2 (e.g., after testing the first transistor Q1 of the DUT 100), the system determines whether another DUT transistor is to undergo CIS testing. If so (YES at 216), the method 200 returns to 204-214 as described above to test the next DUT transistor. At 204 in this example, the method 200 proceeds at 204 with again precharging the test capacitor C1 using the precharge circuit 112, and then disconnecting the precharge circuit 112 at 206 from the test capacitor C1. At 208, the test inductor L1 is again pre-charged to develop the test current IT in the test inductor L1, and the test inductor L1 a is connected at 210, in this case to cause the test current IT to flow from the test inductor L1 into the second device terminal 103 while the precharge circuit 112 is disconnected from the test capacitor C1 (e.g., by connecting the test inductor L1 through the switching circuit S1 to the output “2”). At 212, the second transistor Q2 of the DUT 100 is tested at 212 while the test current IT is flowing into the second device terminal 103, for example by measuring the voltage between the second and third device terminals 103 and 104 using the measurement circuit 115 while the test current IT is flowing into the second device terminal 103. At 214, the method includes determining a fail result for the second transistor Q2 if the measured voltage between the second and third device terminals 103 and 104 exceeds a threshold TH.

Once all the transistors of a given DUT have been tested (NO at 216 in FIG. 2), the DUT 100 is removed from the test system socket at 218, and the method 200 can be repeated for further DUTs 100. In one example, the CIS testing includes automatically discharging the test capacitor C1 after CIS testing of each corresponding DUT transistor Q1, Q2. In another example, the test capacitor C1 is pre-charged prior to CIS testing of the first tested transistor (e.g., Q1), and is selectively discharged following CIS testing of the last tested transistor of a given DUT 100 (e.g., Q2). In this example, a second or subsequent test capacitor pre-charging and disconnection (e.g., at 204 and 206 and FIG. 2) can be omitted in certain implementations and/or intervening pre-charging of the test capacitor C1 can be performed intermittently on an as-needed basis (e.g., based on measurement of the input voltage VIN at the first device terminal 102) under control of the ATE controller 111, wherein omitting unneeded test capacitor discharging and recharging between CIS testing of multiple DUT transistors can help reduce DUT testing time in the ATE 110.

FIG. 2A shows a characterization method 250 the threshold or thresholds in order to characterize device CIS performance and determine the current level (e.g., IL) to be used at 208 in the method 200 of FIG. 2. The threshold or thresholds TH used in production testing can be determined by empirical or programmatic characterization steps. In the example method 250, one or more transistors of multiple DUTs 100 are tested, and the transistor or transistors are tested to incrementally increasing test current levels to determine the switched inductive current at which failure occurs. The method 250 begins at 251 in FIG. 2A with charging the test inductor L1 based on a target current I_L. At 252, the test capacitor C1 is precharged (e.g., using a precharge circuit 112 shown in FIG. 1). At 253 in FIG. 2A, the energy from the test inductor L1 is applied to the tested transistor (e.g., FET), and the part is allowed to cool down at 254 while the junction temperature T_J is monitored (e.g., by the measurement circuit 115 in FIG. 1). Critical tests are performed at 255 in FIG. 2A, such as leakage current measurements, clamp voltage measurements V_CLAMP, and a determination is made at 256 as to whether the part has failed (e.g., the tested transistor exhibits excessive leakage current, excessive clamp voltage levels, excessive junction temperatures are sensed, etc.). If so, (YES at 256), the data is logged at 257 and the characterization method 250 is completed for the currently connected device. Otherwise (NO at 256), the target current is incremented at 258 (e.g., the target test current I_L is set to I_L+I_STEP), and the process 250 is repeated one or more times to incrementally increase the test current until the tested part fails (YES at 256). The logged data is then evaluated with respect to determining an expected or acceptable failure current level based on failure current data for multiple DUTs, and a somewhat lower test current is determined for evaluating transistor CIS performance and reliability of production DUTs (e.g., a percentage of a maximum energy the device 100 can tolerate for a given device design). The threshold or thresholds for production transistor CIS testing are determined and programmed into the controller 111 for automated testing of electronic devices during manufacturing.

FIG. 3 shows a graph 300 with a curve 302 showing the drain-source voltage of the first (e.g., high side) transistor Q1 of the electronic DUT 100 during CIS testing according to an implementation of the method 200. A curve 301 in FIG. 3 shows a control signal that actuates the switching circuit S1 with a falling edge at time TO corresponding to the connection of the previously precharged test inductor L1 to the first device terminal 102. The measured drain-source transistor voltage of the first transistor Q1 in this example rises in response to the delivery of the test current IT to the drain D of the first transistor Q1, with the Zener diode Z1 and the p-n junction diode D1 conducting the test current IT, with the control circuit 106 of the DUT 100 controlled by communications from the test system controller 111 to turn off the first driver circuit DRV1. The test current IT also conducts through the resistor R1, causing a corresponding increase in the gate-source voltage of the tested DUT transistor Q1, which increases the drain-source conduction of the transistor Q1 to increase the amount of the test current IT flowing from the drain D to the source S of the first transistor Q1. The Zener diode Z1 stops conducting based on its Zener voltage rating, resulting in the measured drain-source voltage (e.g., curve 302 in FIG. 3) being clamped at a corresponding clamp voltage VC that helps to ensure that the test transistor Q1 does not enter avalanche mode operation during CIS testing.

FIG. 4 shows a graph 400 with a curve 402 showing the drain-source voltage of the second (e.g., low side) transistor Q2 of the electronic DUT 100 during CIS testing according to an implementation of the method 200. A curve 401 in FIG. 4 shows the switching control signal that actuates the switching circuit S1 with a falling edge at time TO corresponding to the connection of the previously precharged test inductor L1 to the second device terminal 103 for testing the second transistor Q2. The measured drain-source transistor voltage of the first transistor Q2 in this example rises in response to the delivery of the test current IT to the drain D of the second transistor Q2, where the Zener diode Z2 and the p-n junction diode D2 conduct the test current IT. The control circuit 106 is controlled by communications from the test system controller 111 to turn off the second driver circuit DRV2. The test current IT flows through the resistor R2 and causes a corresponding increase in the gate-source voltage of the tested DUT transistor Q2. The gate-source voltage of the second transistor Q2 increases the drain-source conduction of the transistor Q2 to increase the amount of the test current IT flowing from the drain D to the source S of the first transistor Q2. The Zener diode Z2 stops conducting based on its Zener voltage rating, resulting in the measured drain-source voltage (e.g., curve 402 in FIG. 4) being clamped at a corresponding clamp voltage VC that helps to ensure that the test transistor Q2 does not enter avalanche mode operation during CIS testing.

FIGS. 3 and 4 illustrate example test result pass or fail criterion in the form of a voltage threshold value TH. The ATE controller 111 in one example stores a corresponding threshold value TH for each tested transistor (e.g., Q1, Q2) of a given type of DUT 100, and compares the peak value of the measured drain-source voltage (e.g., curves 302 and 304) with the corresponding threshold to determine whether the tested transistor Q1 or Q2 is to be designated as passing or failing that CIS test. The thresholds used for testing the transistors Q1 and Q2 can be the same, but different thresholds TH can be used in other implementations.

Described electronic devices, test systems and methods facilitate high volume CIS testing for integrated transistors in a tested electronic device 100, even where all tested transistor terminals are not externally accessible by way of leads or device terminals of the electronic device 100. This facilitates performance and reliability testing during electronic device manufacturing using automated test equipment. Described example electronic devices also facilitate device performance and reliability in use in a host system after manufacturing by including integrated clamping circuitry to protect integrated transistors from voltage stress effects. The described examples facilitate cost reduction by use of high-volume automated test equipment as well as device performance and reliability improvements with enhanced CIS testing capabilities for manufactured electronic devices 100, with the test equipment providing high-speed CIS testing four power FETs or other integrated device transistors controlled by internal logic through a test program implemented by the test system controller 111.

Modifications are possible in the described examples, and other implementations are possible, within the scope of the claims.

What is claimed is:

1. An electronic device, comprising:
a transistor having first and second transistor terminals and a control terminal;
a control circuit connected to the control terminal;
a first device terminal connected to the first transistor terminal;
a second device terminal connected to the second transistor terminal; and
a clamp circuit connected between the first transistor terminal and the control terminal.

2. The electronic device of claim 1, wherein the control terminal is not directly connected to any device terminal.

3. The electronic device of claim 1, wherein the clamp circuit includes a p-n junction diode and a Zener diode connected in series with one another between the first transistor terminal and the control terminal.

4. The electronic device of claim 3, further comprising a resistor connected between the control terminal and the second transistor terminal.

5. The electronic device of claim 4, wherein:
the p-n junction diode includes a first anode and a first cathode, the first cathode directly connected to the control terminal; and
the Zener diode includes a second anode and a second cathode, the second anode directly connected to the first anode, and the second cathode directly connected to the first transistor terminal.

6. The electronic device of claim 3, wherein:
the p-n junction diode includes a first anode and a first cathode, the first cathode directly connected to the control terminal; and
the Zener diode includes a second anode and a second cathode, the second anode directly connected to the first anode, and the second cathode directly connected to the first transistor terminal.

7. The electronic device of claim 1, further comprising a resistor connected between the control terminal and the second transistor terminal.

8. The electronic device of claim 1, wherein: the first transistor terminal is a drain; the second transistor terminal is a source; and the control terminal is a gate.

9. A test system for testing a transistor of an electronic device under test (DUT), comprising:
a controller;
a test inductor having a first inductor terminal, and a second inductor terminal coupled to a supply;
a switching circuit coupled to the test inductor and having an output adapted to be connected to a first device terminal of the DUT;
an output circuit adapted to be connected to a second device terminal of the DUT;
a measurement circuit configured to measure a voltage between the first and second device terminals;
a test capacitor adapted to be connected to the first device terminal; and
a precharge circuit configured to selectively provide a precharge current to the first device terminal;
wherein the controller is configured to:
operate the precharge circuit in a first precharge mode to provide the precharge current to the first device terminal to precharge the test capacitor when the test capacitor is connected to the first device terminal, and then operate the precharge circuit in a second precharge mode to stop the precharge current to the first device terminal;
selectively operate the switching circuit in a first switching circuit mode to connect the first inductor terminal to a precharge load to develop a test current in the test inductor, and in a second switching circuit mode to connect the first inductor terminal to the output of the switching circuit to cause the test current to flow into the first device terminal while the precharge circuit is in the second precharge mode; and
operate the measurement circuit to measure the voltage between the first and second device terminals while the switching circuit is in the second switching circuit mode and the precharge circuit is in the second precharge mode.

10. The test system of claim 9, wherein the controller is configured to determine a pass or fail result based on the measured voltage between the first and second device terminals.

11. The test system of claim 10, wherein the controller is configured to determine a fail result if the measured voltage between the first and second device terminals exceeds a threshold.

12. The test system of claim 9, wherein:
the switching circuit has a second output adapted to be connected to the second device terminal;
the measurement circuit is configured to measure a second voltage between the second device terminal and a third device terminal;
the test capacitor is adapted to be connected between the first device terminal and the third device terminal; and
the controller is configured to:
selectively operate the switching circuit in a third switching circuit mode to connect the first inductor terminal to the second output of the switching circuit to cause the test current to flow into the second device terminal while the precharge circuit is in the second precharge mode; and
operate the measurement circuit to measure the second voltage between the second device terminal and the third device terminal while the switching circuit is in the third switching circuit mode and the precharge circuit is in the second precharge mode.

13. The test system of claim 12, wherein the controller is configured to determine a pass or fail result based on the measured voltage between the second and third device terminals.

14. The test system of claim 13, wherein the controller is configured to determine a fail result if the measured voltage between the second and third device terminals exceeds a threshold.

15. A method of testing a transistor of an electronic device under test (DUT), the method comprising:
connecting a first capacitor terminal of a test capacitor to a first device terminal of the DUT;
connecting an output circuit to a second device terminal of the DUT;
connecting a second capacitor terminal of the test capacitor to a third device terminal of the DUT;
precharging the test capacitor using a precharge circuit;
disconnecting the precharge circuit from the test capacitor;
precharging a test inductor to develop a test current in the test inductor;
connecting the test inductor to cause the test current to flow from the test inductor into the first device terminal while the precharge circuit is disconnected from the test capacitor; and
testing the transistor of the DUT while the test current is flowing into the first device terminal.

16. The method of claim 15, wherein testing the transistor includes measuring a voltage between the first and second device terminals while the test current is flowing into the first device terminal.

17. The method of claim 16, comprising determining a fail result if the measured voltage between the first and second device terminals exceeds a threshold.

18. The method of claim 15, further comprising, after testing the transistor of the DUT:
again precharging the test capacitor using the precharge circuit;
disconnecting the precharge circuit from the test capacitor;
again precharging the test inductor to develop the test current in the test inductor;
connecting the test inductor to cause the test current to flow from the test inductor into the second device terminal while the precharge circuit is disconnected from the test capacitor; and
testing a second transistor of the DUT while the test current is flowing into the second device terminal.

19. The method of claim 18, wherein testing the second transistor includes measuring a voltage between the second and third device terminals while the test current is flowing into the second device terminal.

20. The method of claim 19, comprising determining a fail result if the measured voltage between the second and third device terminals exceeds a threshold.
